(19) United States
(12) Patent Application Publication
(10) Pub. No.: US 2026/0239643 A1
(43) Pub. Date: Aug. 13, 2026

(54) SEMICONDUCTOR DEVICE

(71) Applicant: Sanken Electric Co., Ltd., Saitama-ken (JP)

(72) Inventors: Taro KONDO, Saitama-ken (JP); Shigenobu Matsuda, Saitama-ken (JP)

(73) Assignee: Sanken Electric Co., Ltd., Saitama-ken (JP)

(21) Appl. No.: 19/467,721

(22) Filed: Feb. 2, 2026

(30) Foreign Application Priority Data
Feb. 10, 2025 (JP) 2025-020006

(51) Int. Cl. H10D 12/00; H10D 62/10; H10D 64/00

(52) U.S. Cl. CPC H10D 12/481; H10D 62/127; H10D 64/117

(57) ABSTRACT

A trench-type IGBT is provided. A gate trench TG and a dummy trench TD are provided. The gate trench TG has a gate conductive portion formed therein via an insulating film. The dummy trench TD has a dummy conductive portion formed therein via an insulating film. The dummy conductive portion is connected to an emitter electrode 21 and extends to an end side of a semiconductor substrate in plan view. The emitter electrode 21 is formed on an interlayer insulating layer formed on the semiconductor substrate. A dummy conductive portion connection opening 20B for connecting the emitter electrode 21 and the dummy conductive portion in the dummy trench TD is formed in the interlayer insulating layer. The dummy conductive portion connection opening 20B is formed, in plan view, in a portion facing an n⁺ layer 17 in the y direction and in a portion on the end side of the semiconductor substrate beyond the n⁺ layer 17.

### CROSS-REFERENCE TO RELATED APPLICATION

This application claims the priority benefit of Japanese application serial no. 2025-020006, filed on Feb. 10, 2025. The entirety of the above-mentioned patent application is hereby incorporated by reference herein and made a part of this specification.

### TECHNICAL FIELD

The disclosure relates to a semiconductor device including an insulated gate trench-type insulated gate bipolar transistor (IGBT).

### BACKGROUND ART

One known form of an insulated gate bipolar transistor (IGBT) is an insulated gate trench-type IGBT in which a gate conductive portion is provided via an insulating film in a trench (groove) formed in a semiconductor substrate. In an insulated gate trench-type IGBT, generally an emitter electrode (first main electrode) is formed on the front surface side, and a collector layer and a collector electrode (second main electrode) connected thereto are formed on the back surface side. The current between these is controlled by the potential of the gate conductive portion in the trench (gate trench). In this case, multiple trenches having gate conductive portions therein are provided in parallel, and each gate conductive portion is connected to a gate metal layer (gate wiring). The potential of the gate conductive portion (gate potential) is commonly controlled across all of the gate trenches.

As described in Patent Document 1 (Japanese Patent Application Laid-Open No. 2002-16252), dummy trenches may be provided between multiple gate trenches having gate conductive portions therein. In the dummy trenches, dummy conductive portions that do not function as the aforementioned gate conductive portions are provided via insulating films. The dummy conductive portions and the gate conductive portions have similar forms that they are provided via insulating films in trenches which penetrate the base layer (p-type layer), but the dummy conductive portions are connected to the emitter electrode. By providing dummy trenches in parallel between multiple gate trenches in place of gate trenches, it is possible to reduce the gate capacitance while ensuring the breakdown voltage in the IGBT. It is also easy to simultaneously manufacture the structures of gate trenches and dummy trenches in a common semiconductor substrate.

In the above structure, the base layer (p-type layer) is exposed on the front surface between adjacent gate trenches or dummy trenches. Patent Document 2 (International Publication No. WO2018/052099) describes providing a high impurity concentration p-type layer (p⁺ layer) on the front surface of the base layer between such trenches. This p⁺ layer not only contributes to reducing resistance between the emitter electrode and the base layer (p-type layer) but also contributes to improving the switching operation by quickly discharging holes during reverse recovery operation of the IGBT.

In the IGBT including the dummy trenches as described above, if steep voltage fluctuation occurs during turn-off, an inversion layer is generated in the base layer (p-type layer) near the sidewall of the dummy trench, which may cause large current (short circuit current between the emitter and collector) and potentially destroy the element. Therefore, there has been a demand for an insulated gate trench-type IGBT that is less likely to suffer from short circuit current during turn-off with such steep voltage fluctuation.

The disclosure provides a semiconductor device.

### SUMMARY

The disclosure has the following configuration.

The semiconductor device according to the disclosure is a semiconductor device, in which current between a first main electrode provided on a front surface side of a semiconductor substrate and a second main electrode provided on a back surface side is controlled by a potential of a gate conductive portion. The semiconductor substrate includes: a first semiconductor region of a first conductivity type; a second semiconductor region of a second conductivity type opposite to the first conductivity type, formed on the front surface side of the first semiconductor region; a third semiconductor region of the first conductivity type, formed on the front surface side of the second semiconductor region and connected to the first main electrode; a fourth semiconductor region of the second conductivity type, formed on a lower surface side of the first semiconductor region; and a plurality of grooves formed to penetrate the second semiconductor region from the front surface side with bottoms reaching the first semiconductor region, extending along a first direction in plan view, and arranged along a second direction different from the first direction. The grooves include: a first groove having the gate conductive portion formed therein via an insulating film; and a second groove having a dummy conductive portion formed therein via an insulating film, the dummy conductive portion being connected to the first main electrode and extending in the first direction to an end side of the semiconductor substrate beyond the third semiconductor region in plan view. The first main electrode is formed on an interlayer insulating layer formed on the semiconductor substrate, and the interlayer insulating layer has a dummy conductive portion connection opening connecting the first main electrode and the dummy conductive portion in the second groove. The dummy conductive portion connection opening is formed in a portion facing the third semiconductor region in the first direction and in a portion on an end side of the semiconductor substrate beyond the third semiconductor region in plan view.

In a case of a length along the first direction of the second groove being L0 and a total length along the first direction of the dummy conductive portion connection opening formed corresponding to the second groove being L1, a value of L1/L0 may be in a range of 0.2 to 0.9.

In a range where the third semiconductor region is formed in the first direction, the third semiconductor region may not be formed on each side surface of the second groove of the semiconductor substrate.

A fifth semiconductor region of the second conductivity type having a higher impurity concentration than the second semiconductor region may exist on an inner surface of a first contact groove formed on a front surface of the semiconductor substrate between the first groove and the second groove that are adjacent to each other, and the first main electrode may be connected to the fifth semiconductor region.

A sixth semiconductor region of the second conductivity type having a higher impurity concentration than the second semiconductor region may exist on an inner surface of a second contact groove formed on the front surface of the semiconductor substrate between the second grooves that are adjacent to each other, and the first main electrode may be connected to the sixth semiconductor region.

The second main electrode may be connected to the fourth semiconductor region on the back surface side of the semiconductor substrate, and in a thickness direction of the semiconductor substrate, a seventh semiconductor region of the first conductivity type having a higher impurity concentration than the first semiconductor region may be provided between the first semiconductor region and the second semiconductor region, and an eighth semiconductor region of the first conductivity type having a higher impurity concentration than the first semiconductor region and being thinner than the seventh semiconductor region may be provided between the first semiconductor region and the fourth semiconductor region, respectively.

According to the disclosure, it is possible to obtain an insulated gate trench-type IGBT that suppresses occurrence of short circuit current during turn-off with steep voltage fluctuation.

### BRIEF DESCRIPTION OF THE DRAWINGS

FIG. 1 is an example of a cross-sectional structure of the conventional semiconductor device in which dummy trenches are used.

FIG. 2 is an example of a planar structure of the conventional semiconductor device in which dummy trenches are used.

FIG. 3 is a planar structure of the semiconductor device according to an embodiment of the disclosure.

FIG. 4 is a cross-sectional structure of the semiconductor device according to an embodiment of the disclosure.

FIG. 5 is a planar structure of a modification example of the semiconductor device according to an embodiment of the disclosure.

FIG. 6 is a cross-sectional structure of a modification example of the semiconductor device according to an embodiment of the disclosure.

### DESCRIPTION OF THE EMBODIMENTS

Hereinafter, a semiconductor device according to an embodiment of the disclosure will be described. In the following description of the drawings, the same or similar parts are denoted by the same or similar reference numerals. However, it should be noted that the drawings are schematic, and the relationship between thickness and planar dimensions, the ratio of lengths of respective parts, etc., may differ from reality. Therefore, specific dimensions should be determined with reference to the following description. It should also be understood that the dimensional relationships and ratios between the drawings may differ from one another. Further, the embodiments shown below exemplify devices for embodying the technical concept of the disclosure, and the technical concept of the disclosure does not limit the shape, structure, arrangement, etc. of components to those described below. The embodiments of the disclosure can be modified in various ways within the scope of the claims. In the disclosure, terms specifying up and down such as “upper” and “lower” are used to facilitate the description. Even when a component is provided on a side surface, the component remains within the scope of the disclosure as long as it is substantially the same as the component of the disclosure. Further, the term “on” includes not only the case where a component is formed in contact with an object, but also the case where the component is formed via another layer. Additionally, in the disclosure, the term “connection” is not limited to direct connection, and indirect connection with an element such as a resistor interposed therebetween remains within the scope of the disclosure as long as it is substantially the same as the component of the disclosure.

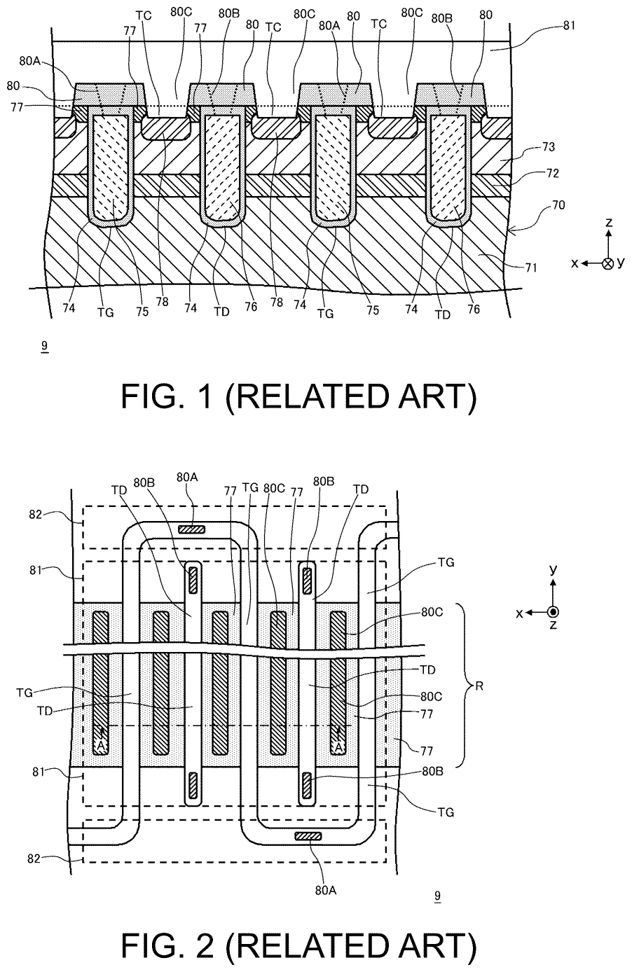

First, the structure and problems of a conventional semiconductor device (IGBT) provided with dummy trenches will be described. FIG. 1 is a cross-sectional view showing the structure of such a conventional semiconductor device 9, and shows a simplified cross-sectional structure of the part constituting an IGBT in the semiconductor device described in Patent Document 2. Here, in the semiconductor substrate 70, a gate trench (first groove) TG that performs switching operation, a dummy trench (second groove) TD including a dummy conductive portion connected to an emitter electrode, and structures around these are shown. The specific planar configuration of the gate trench TG and the dummy trench TD will be described later, but here, the gate trench TG and the dummy trench TD are provided alternately adjacent to each other. FIG. 1 mainly shows the cross-sectional structure of the semiconductor substrate 70, and the electrical connection with electrodes will also be described later. Further, FIG. 1 shows only the structure on the front surface side (emitter side) of the semiconductor substrate 70. The structure on the back surface side (collector side) of the semiconductor substrate 70 is generally known, so description thereof is omitted. In the following, the left-right direction of the paper surface in FIG. 1 (direction in which trenches are adjacent: second direction) is the x direction, the perpendicular direction to the paper surface of FIG. 1 (direction in which each trench extends: first direction) is the y direction, and the up-down direction of the paper surface of FIG. 1 (thickness direction of the semiconductor substrate 70: third direction) is the z direction.

In FIG. 1, in the semiconductor substrate 70 formed of silicon, a high impurity concentration n-type n⁺ layer 72 that serves as a carrier accumulation region and a low impurity concentration p-type (second conductivity type) p⁻ layer 73 that serves as a base region of the IGBT are formed on a thick low impurity concentration n-type (first conductivity type) n⁻ layer 71 that serves as a drift layer in the IGBT. Grooves (trenches) that become the gate trench TG and the dummy trench TD extend in the perpendicular direction to the paper surface (y direction), and are formed to penetrate the p⁻ layer 73 and the n⁺ layer 72 from the front surface of the semiconductor substrate 70, with bottoms positioned in the n⁻ layer 71. In the gate trench TG and the dummy trench TD, a thin oxide film 74 is formed on the inner surface, and then a gate conductive portion 75 and a dummy conductive portion 76 are respectively formed to fill the inside of the grooves.

In FIG. 1, the gate trench TG and the dummy trench TD have equivalent widths and depths to each other, and the same applies to the oxide film 74 therein. Further, the gate conductive portion 75 and the dummy conductive portion 76 include the same material, and as described later, the gate conductive portion 75 is connected to adjacent gate conductive portions 75, and both dummy conductive portions 76 are connected to an emitter electrode 81. Therefore, in the semiconductor substrate 70, the gate trench TG and the dummy trench TD (oxide film 74, gate conductive portion 75, and dummy conductive portion 76) are manufactured simultaneously in a common process.

In the semiconductor substrate 70, each of the trenches TG and TD is formed to penetrate the n⁺ layer 77 that is shallowly formed on the front surface of the p⁻ layer 73, so the n⁺ layer 77 that serves as a source region respectively exists on both side surfaces of each of the trenches TG and TD. A high impurity concentration p-type p⁺ layer 78 that serves as a contact layer to the p⁻ layer 73 is formed between the n⁺ layers 77 that exist in association with the side surfaces of two adjacent trenches TG and TD. In the part of the semiconductor substrate 70 where the p⁺ layer 78 is formed, a contact trench TC is formed, which is a groove shallower than the gate trench TG. On the inner surface of the contact trench TC, the p⁺ layer 78 is exposed on the bottom surface side and the n⁺ layer 77 is exposed on the side surface side, respectively. Therefore, formation of an electrode (emitter electrode 81) in this contact trench TC can connect the n⁺ layer 77 and the p⁺ layer 78 to the emitter electrode 81.

An interlayer insulating layer 80 is formed on the semiconductor substrate 70, and connection to the gate conductive portion 75 and electrical connection between the dummy conductive portion 76, the n⁺ layer 77, the p⁺ layer 78 and the emitter electrode 81 are performed via openings (through holes) locally formed in the interlayer insulating layer 80. Therefore, three types of openings are formed in the interlayer insulating layer 80: opening 80A for forming connection to the gate conductive portion 75, opening 80B for forming connection to the dummy conductive portion 76, and opening 80C for forming connection to the n⁺ layer 77 and the p⁺ layer 78. A cross-section of the location where the opening 80C is formed (A-A direction in FIG. 2 described later) is shown in FIG. 1. The emitter electrode 81 formed on the interlayer insulating layer 80 is in contact with the p⁺ layer 78 on the front surface of the contact trench TC and the n⁺ layers 77 on the left and right through the conductor in the opening 80C.

FIG. 2 is a diagram schematically showing a part of the planar structure on the front surface side in the above semiconductor device 9. Here, the planar shapes of the gate trench TG, the dummy trench TD, the openings 80A to 80C, and the n⁺ layer 77 are shown. In FIG. 2, the dimensional ratios of each part along the x direction are shown differently from FIG. 1 for convenience. Here, since the opening 80C substantially overlaps with the p⁺ layer 78 and the contact trench TC, the p⁺ layer 78 and the contact trench TC are not illustrated in FIG. 2.

Furthermore, in FIG. 2, the planar shapes of the emitter electrode (first main electrode) 81 and the gate metal layer (gate wiring) 82, which are metal layers formed on the interlayer insulating layer 80 corresponding to this structure, are illustrated with broken lines. The emitter electrode 81 and the gate metal layer 82 are respectively connected to the gate conductive portion 75, the dummy conductive portion 76, the n⁺ layer 77, and the p⁺ layer 78 via conductors in the openings 80A, 80B, and 80C in the interlayer insulating layer 80 as described above. In practice, the structure of FIG. 2 is uniformly formed over a wider range along the x direction and the y direction.

In FIG. 2, the gate trench TG extends in the y direction beyond the dummy trench TD in plan view, and is folded back in a U-shape on both end sides in the y direction to extend in the opposite direction. Therefore, the gate trench TG is formed integrally over a wide range of the front surface of the semiconductor substrate 70. The dummy trench TD is formed at a position between partially adjacent gate trenches TG. In FIG. 2, multiple dummy trenches TD and contact trenches TC, each extending in the y direction, are formed independently, and each has a stripe-like configuration.

In the structure of FIG. 2, an active region R, which is a region inside the region where the n⁺ layer 77 forming the outermost source region in the x direction and the y direction is formed, functions as an IGBT (MOSFET that serves as a part of the IGBT).

Within the active region R, the gate trenches TG and the dummy trenches TD all extend along the y direction, and the gate trenches TG and the dummy trenches TD are alternately provided in the x direction. FIG. 1 shows the cross-sectional structure within the active region R.

In the structure described in Patent Document 2, a p⁺ layer is formed on the front surface of the semiconductor substrate outside the n⁺ layer 77 in FIG. 2 (outside the active region R). The emitter electrode is also connected to this p⁺ layer. As a result, the emitter electrode is connected to the base region even outside the active region. Here, since the structure of this region is irrelevant to the technical features of the disclosure, this p⁺ layer is omitted in FIG. 2.

In FIG. 2, the opening 80A is locally formed directly below the gate metal layer (gate wiring) 82 provided outside the active region R. Additionally, the opening 80C (contact trench TC, p⁺ layer 78) is an opening that extends long in the y direction along the gate trench TG and the dummy trench TD therebetween within the active region R. By extending the opening 80C long and providing a long region in the y direction where the emitter electrode 81 connects to the n⁺ layer 77 and the p⁺ layer 78, the switching characteristics of the semiconductor device are accelerated. However, in an IGBT capable of high-speed operation, steep voltage fluctuation occurs during turn-off as described later, and a voltage distribution occurs along the longitudinal direction (y direction) within the dummy trench TD, which may cause short circuit current to flow.

Further, the opening 80B is locally formed only on both end sides of the dummy trench TD in the y direction (outside the active region R), and the opening 80A is formed closer to the end side of the semiconductor substrate 70 in the y direction than the opening 80B. As shown in FIG. 2, each emitter electrode 81 is connected to the dummy conductive portion 76, the n⁺ layer 77, and the p⁺ layer 78 via conductors within the openings 80B and 80C. The emitter electrode 81 and the gate metal layer 82 are formed by dividing and patterning a metal layer formed on the interlayer insulating layer 80 as shown in FIG. 2.

Normally, the dummy conductive portion 76 within the dummy trench TD is not connected to the gate electrode 81 but is connected to the emitter electrode. Therefore, regardless of the gate potential, no n-type channel is formed in the p⁻ layer 73 on the side surface of the dummy trench TD, and no current flows along the side surface of the dummy trench TD. As described in Patent Document 1, etc., the depletion layer formed around the dummy trench TD when the IGBT is off contributes to increasing the breakdown voltage of this IGBT.

The inventors found that in the case of performing high-speed operation on the above semiconductor device 9 by steeply changing the gate voltage from on to off (during turn-off), a channel may be generated along the side surface of the dummy trench TD, and short circuit current may flow.

The following was presumed to be the cause. In response to a steep potential change occurring in the semiconductor substrate 70 during turn-off, a depletion layer spreads in the n⁻ layer 71. Then, the capacitance between the collector and dummy conductive portion changes, and displacement current flows through the oxide film 74 between the n⁻ layer 71 and the dummy conductive portion 76 in the dummy trench TD. Due to this, a potential difference occurs between a local portion of the dummy conductive portion 76 and the opening 80B side (the potential of the local portion of the dummy conductive portion 76 is raised). Then, due to this potential difference, an n-type channel is generated in the portion of the opposing p-type base layer (p⁻ layer) 73. It was presumed that short circuit current flows to the nearby emitter electrode 81 through the current path of this n-type channel.

In the structure of FIG. 2, the opening 80C is an opening that is long in the y direction and is formed in the long portion of the active region R in the y direction. As semiconductor devices become smaller due to miniaturization, the pitch between the contact trench TC and the dummy trench TD has become narrower. Accordingly, as in Patent Document 2, the opening 80B is provided only on both end sides of the dummy trench TD to secure the distance between the opening 80B and the opening 80C. Then, the problem described above is likely to occur.

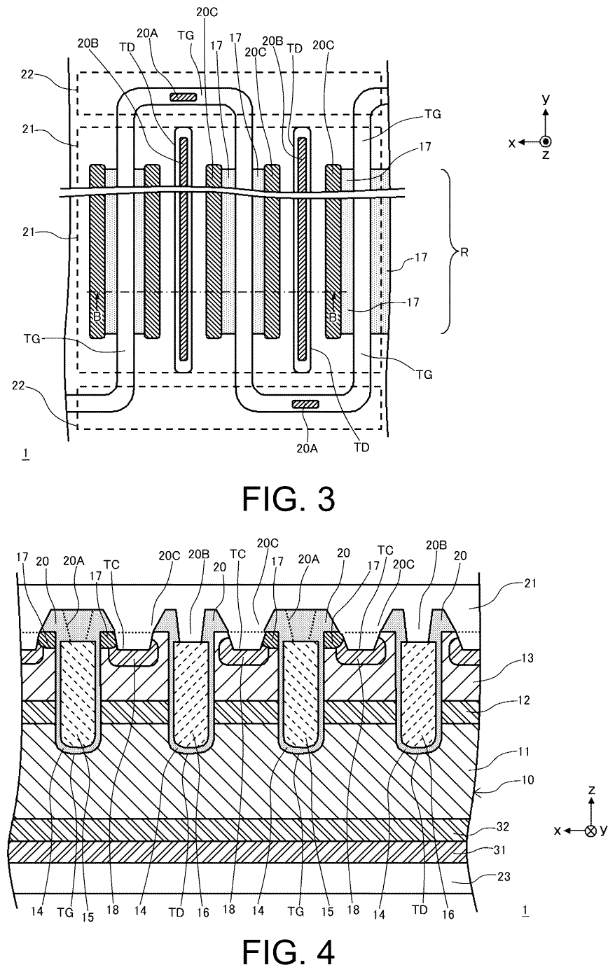

Considering the above, FIG. 3 shows a plan view, corresponding to FIG. 2, of a semiconductor device 1 according to the form of the disclosure that suppresses the generation of voltage in such a dummy conductive portion. Here, a gate trench (first groove) TG and a dummy trench (second groove) TD are formed in a similar manner to FIG. 2. An opening (gate conductive portion connection opening) 20A, an opening (dummy conductive portion connection opening) 20B, and an opening (base connection opening) 20C corresponding to the aforementioned openings 80A, 80B, and 80C are formed as illustrated. Then, an emitter electrode (first main electrode) 21 and a gate metal layer (gate wiring) 22 respectively corresponding to the aforementioned emitter electrode 81 and gate metal layer 82 are illustrated in a similar manner. Further, an n⁺ layer 17 (source region: third semiconductor region) corresponding to the aforementioned n⁺ layer 77 and an active region R are also illustrated in a similar manner. It is noted that, similar to FIG. 2, the contact trench TC is not illustrated, but the shape of the opening 20C reflects the shape of the contact trench TC.

The opening (dummy conductive portion connection opening) 20B in FIG. 3 is formed elongated to extend in the y direction within the active region R. The dummy trench (second groove) TD extends to the outside beyond the active region R in the y direction, and the opening 20B also extends to the outside beyond the active region R in the y direction. Further, while in FIG. 2, the n⁺ layer 77 is uniformly formed around the gate trench TG and the dummy trench TD in the active region R, in FIG. 3, the n⁺ layer 17 is formed only around the gate trench TG and is not formed to contact the side surface of the dummy trench TD.

Although the opening 20B cannot be extended to the gate wiring 22 in the y direction, the dummy conductive portion 16 and the dummy trench TD may be extended directly below the gate wiring 22 as long as the dummy conductive portion 16 and the dummy trench TD do not reach the gate trench TG. Further, for example, the n⁺ layer 17 may be formed only in a region closer to the gate trench TG side than the contact trench TC in the x direction as shown in FIG. 3.

Furthermore, FIG. 4 is a cross-sectional view of this semiconductor device 1 corresponding to the B-B direction in FIG. 3, and corresponds to FIG. 1. Unlike FIG. 1, the structure on the back surface side of the semiconductor substrate 10 is also illustrated here, and the structure on the back surface side will be described later. In this semiconductor substrate 10, an n⁻ layer 11 (drift layer: first semiconductor region), an n⁺ layer 12 (carrier accumulation region: seventh semiconductor region), and a p⁻ layer 13 (base region: second semiconductor region) are formed in a similar manner to the n⁻ layer 71, the n⁺ layer 72, and the p⁻ layer 73 in FIG. 1, and the gate trench TG and the dummy trench TD are formed as well. An oxide film (insulating film) 14, a gate conductive portion 15, a dummy conductive portion 16, a p⁺ layer (fifth semiconductor region) 18, and a contact trench TC are also formed. However, the n⁺ layer 17 (source region: third semiconductor region) is not formed to reach the sidewall of the dummy trench TD. Then, the interlayer insulating layer 20 differs from the opening configuration of the interlayer insulating layer 80 in FIG. 1, particularly in the configuration of openings formed therein. The cross-section of FIG. 4 is a cross-section at locations where the opening 20B and the opening 20C are present.

In FIG. 3, the opening 20B is formed in a region where the n⁺ layer 17 exists in the y direction, and in a portion closer to the end side of the semiconductor substrate 10 than the n⁺ layer 17. For example, in FIG. 3, the opening 20B includes a portion facing the n⁺ layer 17 along the y direction, and is formed in a long stripe shape extending to the end side of the semiconductor substrate 10 from the portion facing the n⁺ layer 17. With this configuration, each dummy conductive portion 16 is in contact with the emitter electrode 21 over a wide range in the y direction, and accordingly, the portion where the dummy conductive portion 16 is not in direct contact with the emitter electrode 21 becomes short. Therefore, even in the case of displacement current flowing in the dummy conductive portion 16 during turn-off of the semiconductor device, a local potential distribution in the dummy conductive portion 16 can be suppressed. This makes it possible to suppress formation of an n-type channel along the sidewall of the dummy trench TD, and to suppress short circuit current from flowing. Additionally, in FIG. 4, the width of the opening 20B in the x direction is narrower than the width of the dummy trench TD in the x direction, and the interlayer insulating film 20 is provided on the opening portion of the dummy trench TD. Therefore, even in the case of a channel being generated along the sidewall of the dummy trench TD, the distance to the emitter electrode 21 in the nearest contact trench TC is secured. Therefore, short circuit current can be reduced. Furthermore, the n⁺ layer 17 on the dummy trench TD side relative to the contact trench TC is not in contact with the sidewall of the dummy trench TD, or more preferably the n⁺ layer 17 is not provided. Accordingly, the Schottky barrier with the channel is large, so the resistance from the channel to the nearest contact trench TC becomes large, and the supply of electrons decreases. As a result, short circuit current can be reduced.

Although in the structure of FIG. 3, the opening 20B is formed in a long stripe shape along the y direction, the opening 20B may be divided in the y direction and formed by multiple holes. For example, in the case of the length along the y direction of the portion of the dummy conductive portion 16 that is not in direct contact with the emitter electrode 21 being short, and the total length of the portion of the dummy conductive portion 16 that is in direct contact with the emitter electrode 21 (opening 20B) being sufficiently long, it is clear that similar effects are achieved. Specifically, it is desirable that the length of the portion of the dummy conductive portion 16 that is not in direct contact with the emitter electrode 21 is less than 50 μm, and more preferably less than 25 μm. Further, in the case of the length along the y direction of the dummy trench TD being L0, and the total length along the y direction of the opening 20B with respect to this dummy trench TD being L1, the range of L1/L0 is preferably in the range of 0.2 to 0.9. For example, in the case of the opening 20B being divided in the y direction and formed by multiple holes, it is preferable to satisfy that the length of the portion of the dummy conductive portion 16 that is not in direct contact with the emitter electrode 21 is less than 50 μm, and more preferably less than 25 μm, and the range of L1/L0 is in the range of 0.2 to 0.4. Further, in the case of the opening 20B being formed in a long stripe shape along the y direction as shown in FIG. 3, the range of L1/L0 is preferably in the range of 0.7 to 0.9. Here, since the thickness of the oxide film 14 in FIG. 4 is negligible compared to the length L0 along the y direction of the dummy trench TD, L0 is also substantially the length of the dummy conductive portion 16.

As shown in FIG. 4, it is desirable that the n⁺ layer 17 serving as the source region not formed so far as to reach the sidewall of the dummy trench TD. Accordingly, even in the case of displacement current flowing into the dummy conductive portion 16 during turn-off of the semiconductor device and causing a local n-type channel to be formed on the sidewall of the dummy trench TD. it is possible to suppress short circuit current from flowing. Nevertheless, even in the case of the n⁺ layer 17 serving as the source region being formed to reach the sidewall of the dummy trench TD, formation of the n-type channel can be suppressed as long as the total length where the dummy conductive portion 16 and the emitter electrode 21 are connected is sufficiently long, and it is clear that similar effects are achieved.

Additionally, the p⁺ layer 18 at the bottom of the contact trench TC in which the emitter electrode 21 is embedded is formed in a region adjacent to the dummy trench TD in the same manner as in a region adjacent to the gate trench TG. Accordingly, the contact area between the emitter electrode 21 and the p+layer 18 can be increased, and the resistance between the emitter electrode 21 and the region of the p⁻ layer 13 (base region) adjacent to the dummy trench TD can be reduced.

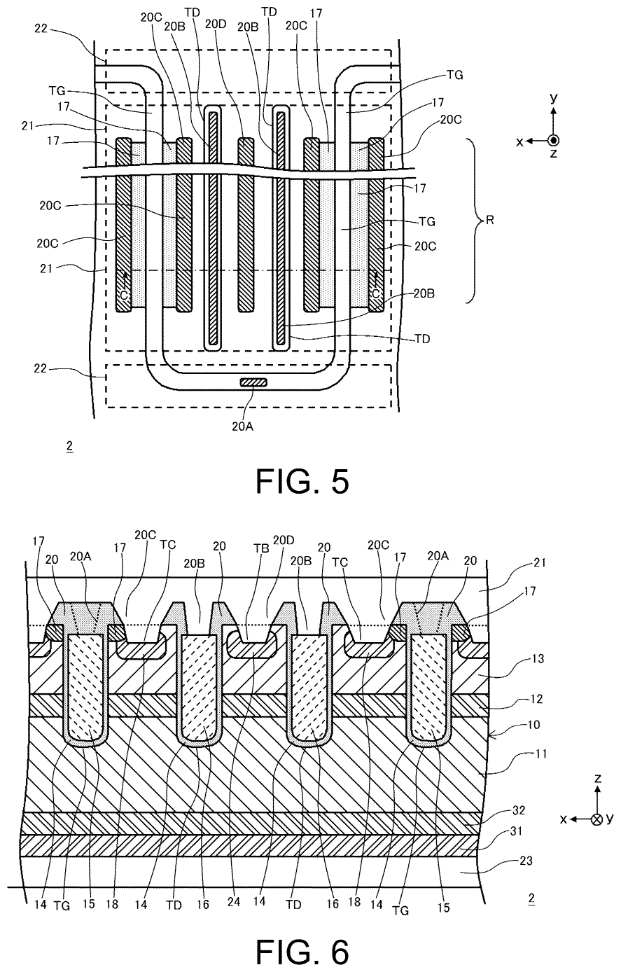

Further, in the structure of FIG. 4, the gate trenches TG and the dummy trenches TD are arranged alternately in the y direction. That is, one dummy trench TD is provided between two adjacent gate trenches TG (for example, two portions extending in the y direction and adjacent in the x direction in one gate trench TG as shown in FIG. 4). However, in order to secure the breakdown voltage of the IGBT, the planar structure shown in FIG. 3 can be modified to provide two or more dummy trenches TD between two adjacent gate trenches TG. FIG. 5 is a plan view, corresponding to FIG. 3, of a semiconductor device 2 in which two dummy trenches TD are provided between two gate trenches TG in this manner. FIG. 6 is a cross-sectional view, corresponding to FIG. 4, of this semiconductor device 2. FIG. 6 corresponds to a cross-section in the C-C direction in FIG. 5.

In the structure of FIG. 3 and FIG. 4, all the contact trenches TC for connection between the base region and the emitter electrode 21 and the associated openings 20C are provided between the gate trenches TG and the dummy trenches TD. In contrast thereto, the structure of FIG. 5 and FIG. 6 has two types of structures for connection between the base region and the emitter electrode 21: a contact trench (first contact groove) TC and an opening 20C provided between the gate trench TG and the dummy trench TD similarly to the structure of FIG. 3 and FIG. 4; and a contact trench (second contact groove) TB and an opening 20D provided between the dummy trenches TD, and these are shown distinctly. Correspondingly, the p⁺ layer provided under the contact trench TB for connection with the base region is designated as p⁺ layer (sixth semiconductor region) 24, to be distinguished from the aforementioned p⁺ layer (fifth semiconductor region) 18. As shown in FIG. 6, the side surface of the contact trench TC is in contact with the n⁺ layer (third semiconductor region) 17, whereas the side surface of the contact trench TB is not in contact with the n⁺ layer 17 at all.

In this structure, the relationship between the length (or total length) L1 in the y direction of the portion of the dummy conductive portion 16 that is in direct contact with the emitter electrode 21 (opening 20B) and the length L0 along the y direction of the dummy trench TD (or dummy conductive portion 16) is also set to be the same as described above, thereby suppressing formation of an n-type channel along the sidewall of the dummy trench TD during turn-off of the semiconductor device. Further, the width of the opening 20B in the x direction is narrower than the width of the dummy trench TD in the x direction, and the interlayer insulating film 20 is provided on the opening portion that serves as the dummy trench TD in the semiconductor substrate 10. This secures the distance from the sidewall of the dummy trench TD to the emitter electrode 21 in the nearest contact trench TC.

Further, as shown in FIG. 6, in this structure, it is also desirable that the n⁺ layer 17 is not formed on the side surface of the dummy trench TD, and it is desirable that the n⁺ layer 17 is provided only on the gate trench TG side rather than on the contact trench TC side.

In FIG. 5, the aforementioned contact trench TB may be formed along the y direction similar to the contact trench TC, but the forms of the contact trench TB and the contact trench TC need not be the same. For example, the contact trench TB and the p⁺ layer 24 may be changed to multiple dot shapes divided in the y direction. The impurity concentration of the p⁺ layer 24 under the contact trench TB and the impurity concentration of the p⁺ layer 18 under the contact trench TC need not be the same.

As shown in FIG. 6, it is desirable that there is no n⁺ layer 17 at all on the upper surface of the semiconductor substrate 10 between two adjacent dummy trenches TD. In addition, on the upper surface of the semiconductor substrate 10 between the gate trench TG and the dummy trench TD, the n⁺ layer 17 is provided only on the gate trench TG side rather than the contact trench TC side in the x direction, and it is desirable that no n⁺ layer 17 is provided on the upper surface of the semiconductor substrate 10 between the dummy trenches TD. It is noted that even if the n⁺ layer 17 is provided on the upper surface of the semiconductor substrate 10 from the side surface of the gate trench TG to the side surface of the dummy trench TD between the gate trench TG and the dummy trench TD, it is desirable not to dispose the n⁺ layer 17 on the upper surface of the semiconductor substrate 10 from the side surface of one dummy trench TD to the side surface of another dummy trench TD between the dummy trenches TD. In this case, since no n⁺ layer 17 is provided between the dummy trenches TD, even if an n-type channel is formed in the dummy trench TD, short circuit current is suppressed from flowing through the n⁺ layer 17 from the n-type channel.

Next, the structure on the back surface side of the semiconductor substrate 10 will be described. In FIG. 4 and FIG. 6, a p⁺ layer 31 (collector layer: fourth semiconductor region) of p-type with high impurity concentration is formed on the most back surface side of the semiconductor substrate 10, and a collector electrode (second main electrode) 23 is formed to be in contact with this p⁺ layer 31. This enables the active region R of the semiconductor devices 1 and 2 to operate as IGBT. In this case, an n⁺ layer 32 of n-type with higher impurity concentration than the n-layer 11 is formed between the p⁺ layer 31 (collector layer) and the n-layer 11 (drift layer). Therefore, in the semiconductor devices 1 and 2, the n⁺ layer (seventh semiconductor region) 12 and the n⁺ layer (collector side high impurity concentration layer: eighth semiconductor region) 32 with higher impurity concentration than the low impurity concentration n-layer 11 (drift layer) are formed on the upper side and lower side thereof, respectively.

A semiconductor device having high impurity concentration layers respectively above and below the drift layer in this manner is described in, for example, Japanese Patent Application Laid-Open No. 2005-57028. A thick n⁺ layer (seventh semiconductor region) 12 is provided on the n-layer 11, and an n⁺ layer (collector side high impurity concentration layer: eighth semiconductor region) 32 that has higher concentration than the n⁺ layer 12 and is thinner than the n⁺ layer 12 is provided below the n-layer 11. This can reduce hole injection from the p⁺ layer 31 (collector layer) to the n-layer 11 and reduce switching loss.

In IGBTs capable of high-speed operation in this manner, a voltage distribution occurs as described above along the longitudinal direction within the dummy trench TD in the case of switching from on to off, which often causes short circuit current to flow. The configurations of the semiconductor devices 1 and 2 described above, which suppress the occurrence of such voltage distribution, are particularly effective in such cases.

The structure on the back surface side may be appropriately set as well. Additionally, the planar shapes of the gate trenches and dummy trenches as shown in FIG. 3, etc. may also be appropriately set as long as similar operation can be performed.

Further, other layers can be appropriately added to or deleted from the semiconductor substrate. It is also clear that similar configurations can be applied by reversing all p-type and n-type in the semiconductor in the above examples.

What is claimed is:

1. A semiconductor device, in which current between a first main electrode provided on a front surface side of a semiconductor substrate and a second main electrode provided on a back surface side is controlled by a potential of a gate conductive portion,
wherein the semiconductor substrate comprises:
a first semiconductor region of a first conductivity type;
a second semiconductor region of a second conductivity type opposite to the first conductivity type, formed on the front surface side of the first semiconductor region;
a third semiconductor region of the first conductivity type, formed on the front surface side of the second semiconductor region and connected to the first main electrode;
a fourth semiconductor region of the second conductivity type, formed on a lower surface side of the first semiconductor region; and
a plurality of grooves formed to penetrate the second semiconductor region from the front surface side with bottoms reaching the first semiconductor region, extending along a first direction in plan view, and arranged along a second direction different from the first direction,
wherein the grooves comprise:
a first groove having the gate conductive portion formed therein via an insulating film; and
a second groove having a dummy conductive portion formed therein via an insulating film, the dummy conductive portion being connected to the first main electrode and extending in the first direction to an end side of the semiconductor substrate beyond the third semiconductor region in plan view,
wherein the first main electrode is formed on an interlayer insulating layer formed on the semiconductor substrate, and the interlayer insulating layer has a dummy conductive portion connection opening connecting the first main electrode and the dummy conductive portion in the second groove, and
wherein the dummy conductive portion connection opening is formed in a portion facing the third semiconductor region in the first direction and in a portion on an end side of the semiconductor substrate beyond the third semiconductor region in plan view.

2. The semiconductor device according to claim 1, wherein in a case of a length along the first direction of the second groove being L0 and a total length along the first direction of the dummy conductive portion connection opening formed corresponding to the second groove being L1, a value of L1/L0 is in a range of 0.2 to 0.9.

3. The semiconductor device according to claim 1, wherein in a range where the third semiconductor region is formed in the first direction, the third semiconductor region is not formed on each side surface of the second groove of the semiconductor substrate.

4. The semiconductor device according to claim 1, wherein a fifth semiconductor region of the second conductivity type having a higher impurity concentration than the second semiconductor region exists on an inner surface of a first contact groove formed on a front surface of the semiconductor substrate between the first groove and the second groove that are adjacent to each other, and the first main electrode is connected to the fifth semiconductor region.

5. The semiconductor device according to claim 4, wherein a sixth semiconductor region of the second conductivity type having a higher impurity concentration than the second semiconductor region exists on an inner surface of a second contact groove formed on the front surface of the semiconductor substrate between the second grooves that are adjacent to each other, and the first main electrode is connected to the sixth semiconductor region.

6. The semiconductor device according to claim 1, wherein the second main electrode is connected to the fourth semiconductor region on the back surface side of the semiconductor substrate, and
in a thickness direction of the semiconductor substrate,
a seventh semiconductor region of the first conductivity type having a higher impurity concentration than the first semiconductor region is provided between the first semiconductor region and the second semiconductor region, and an eighth semiconductor region of the first conductivity type having a higher impurity concentration than the first semiconductor region and being thinner than the seventh semiconductor region is provided between the first semiconductor region and the fourth semiconductor region, respectively.

7. The semiconductor device according to claim 2, wherein in a range where the third semiconductor region is formed in the first direction, the third semiconductor region is not formed on each side surface of the second groove of the semiconductor substrate.

8. The semiconductor device according to claim 2, wherein a fifth semiconductor region of the second conductivity type having a higher impurity concentration than the second semiconductor region exists on an inner surface of a first contact groove formed on a front surface of the semiconductor substrate between the first groove and the second groove that are adjacent to each other, and the first main electrode is connected to the fifth semiconductor region.

9. The semiconductor device according to claim 2, wherein the second main electrode is connected to the fourth semiconductor region on the back surface side of the semiconductor substrate, and
in a thickness direction of the semiconductor substrate,
a seventh semiconductor region of the first conductivity type having a higher impurity concentration than the first semiconductor region is provided between the first semiconductor region and the second semiconductor region, and an eighth semiconductor region of the first conductivity type having a higher impurity concentration than the first semiconductor region and being thinner than the seventh semiconductor region is provided between the first semiconductor region and the fourth semiconductor region, respectively.
